(19) United States
(12) Patent Application Publication
(10) Pub. No.: US 2025/0385201 A1
(43) Pub. Date: Dec. 18, 2025

(54) SEMICONDUCTOR DEVICE AND METHOD FOR MANUFACTURING SAME

(71) Applicant: Microchip Technology Incorporated, Chandler, AZ (US)

(72) Inventors: Shesh Mani Pandey, Gilbert, AZ (US); Yogesh Kumar Sharma, Colorado Springs, CO (US); Dennis Meyer, Chandler, AZ (US); George Dorman, Chandler, AZ (US)

(73) Assignee: Microchip Technology Incorporated, (US)

(21) Appl. No.: 18/948,736

(22) Filed: Nov. 15, 2024

Related U.S. Application Data
(60) Provisional application No. 63/661,464, filed on Jun. 18, 2024.

(51) Int. Cl. H01L 23/64; H01L 29/423; H01L 29/49

(52) U.S. Cl. CPC H01L 23/647; H10D 64/519; H10D 64/662

(57) ABSTRACT

A semiconductor device that may include an outer ring formed within an active region wherein the outer ring is operatively connected to the active region. A contact pad formed within an inner ring wherein the contact pad is operatively connected to the inner ring. An insulating region formed between the outer ring and the inner ring. A removable finger formed between the outer ring and the inner ring wherein the removable finger operatively connects the outer ring to the inner ring.

### CROSS-REFERENCE TO RELATED APPLICATION

The present application claims priority to U.S. Provisional Patent Application No. 63/661,464, filed on Jun. 18, 2024, the contents of which are hereby incorporated by reference in their entirety.

### TECHNICAL FIELD

The present disclosure relates generally to semiconductor devices, and more specifically to metal oxide semiconductor field effect transistors (MOSFETs) and methods for manufacturing same to optimize the circuit performance by tuning the gate resistance of the MOSFET.

### SUMMARY

According to an aspect of one or more examples, there is provided a semiconductor device that may include an active region, an outer ring formed within the active region, the outer ring is operatively connected to the active region, an inner ring formed within the outer ring, a contact pad formed within the inner ring, the contact pad is operatively connected to the inner ring, an insulating region formed between the outer ring and the inner ring, and a removable finger formed between the outer ring and the inner ring, the removable finger operatively connects the outer ring to the inner ring. The active region may comprise an n-type dopant. The active region may comprise a p-type dopant. The contact pad may comprise a metal. The outer ring may comprise polysilicon. The inner ring may comprise polysilicon. The removable finger may comprise polysilicon.

According to an aspect of one or more examples, there is provided a semiconductor device that may include an active region, an outer ring formed within the active region, the outer ring is operatively connected to the active region, an inner ring formed within the inner ring, a contact pad formed within the inner ring, the contact pad is operatively connected to the inner ring, an insulating region formed between the outer ring and the inner ring, and a plurality of removable fingers formed between the outer ring and the inner ring, the plurality of removable fingers operatively connects the outer ring to the inner ring. The active region may comprise an n-type dopant. The active region may comprise a p-type dopant. The contact pad may comprise a metal. The outer ring may comprise polysilicon. The inner ring may comprise polysilicon. The plurality of removable fingers may comprise polysilicon.

According to an aspect of one or more examples, there is provided method of manufacturing a semiconductor device. The method may include forming an active region, forming an outer ring within the active region, the outer ring is operatively connected to the active region, forming an inner ring within the outer ring, forming a contact pad within the inner ring, the contact pad is operatively connected to the inner ring, forming an insulating region between the outer ring and the inner ring, and forming a removable finger between the outer ring and the inner ring, the removable finger operatively connecting the outer ring to the inner ring. The active region may comprise an n-type dopant. The active region may comprise a p-type dopant. The contact pad may comprise a metal. The outer ring may comprise polysilicon. The inner ring may comprise polysilicon. The removable finger may comprise polysilicon. The method may comprise forming a plurality of removable fingers. The plurality of removable fingers may comprise polysilicon.

### BRIEF DESCRIPTION OF DRAWINGS

FIG. 1 shows an illustration of a semiconductor device with one removable finger according to one or more examples.

FIG. 2 shows an illustration of a semiconductor device with a plurality of removable fingers according to one or more examples.

FIG. 3A shows an illustration of a semiconductor device with a plurality of removable fingers with one removable finger marked for removal according to one or more examples.

FIG. 3B shows an illustration of the semiconductor device of FIG. 3A with a plurality of removable fingers with one removable finger removed according to one or more examples.

FIG. 4A shows an illustration of a semiconductor device with a plurality of removable fingers with three removable fingers marked for removal according to one or more examples.

FIG. 4B shows an illustration of the semiconductor device of FIG. 4A with a plurality of removable fingers with three removable fingers removed according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

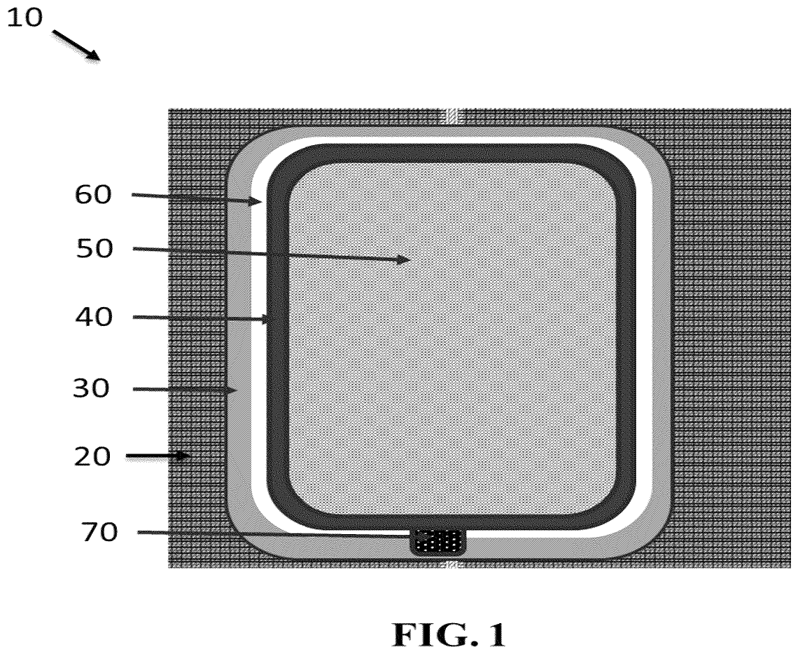

FIG. 1 shows an illustration of a semiconductor device 10 according to one or more examples. The semiconductor device 10 may represent a transistor, and may be called a MOSFET, without limitation. Semiconductor device 10 may include an active region 20. The active region 20 may comprise an n-type dopant or the active region 20 may comprise a p-type dopant. An outer ring 30 may be formed within the active region 20. The outer ring 30 may be operatively connected to the active region 20. The outer ring 30 may comprise polysilicon. An inner ring 40 may be formed within the outer ring 30. The inner ring 40 may comprise polysilicon. A contact pad 50 may be formed within the inner ring 40. The contact pad 50 may be operatively connected to the inner ring 40. The contact pad 50 may comprise a metal. An insulating region 60 may be formed between the outer ring 30 and the inner ring 40. The insulating region 60 may comprise polysilicon, silicon dioxide or a mixture of polysilicon and silicon dioxide or any other insulating material or a mixture of all these. As shown in FIG. 1, a removable finger 70 may be formed between the outer ring 30 and the inner ring 40. The removable finger 70 may operatively connect the outer ring 30 to the inner ring 40. The removable finger 70 may comprise polysilicon. As shown in FIG. 1, with only a single removable finger 70, there may be a very high resistance for the connection between the active region 20 and the contact pad 50 which is determinative of the resistance of the semiconductor device 10, e.g., the gate resistance of the transistor.

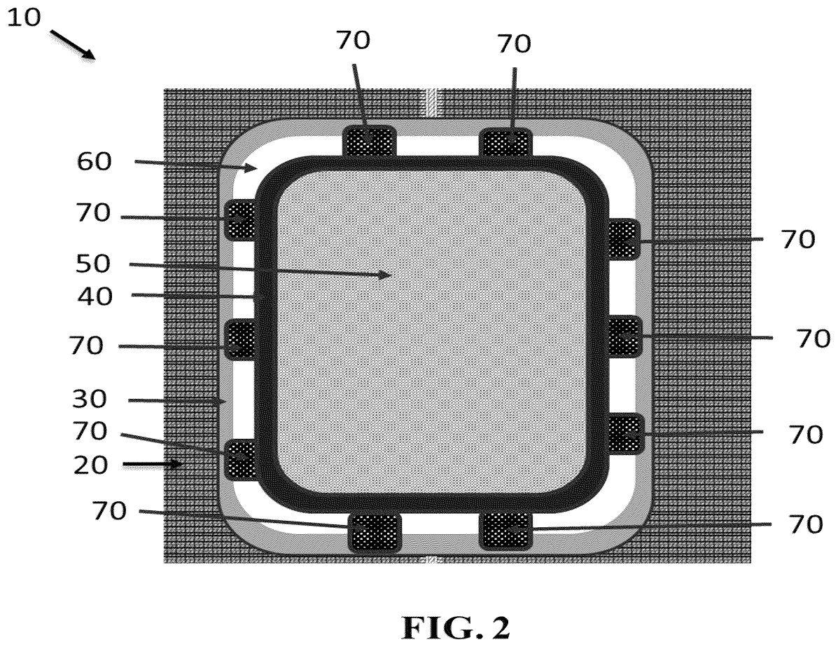

FIG. 2 shows an illustration of a semiconductor device 10 according to one or more examples. The semiconductor device 10 may represent a transistor, and may be called a MOSFET, without limitation. Semiconductor device 10 may include an active region 20. The active region 20 may comprise an n-type dopant or the active region 20 may comprise a p-type dopant. An outer ring 30 may be formed within the active region 20. The outer ring 30 may be operatively connected to the active region 20. The outer ring 30 may comprise polysilicon. An inner ring 40 may be formed within the outer ring 30. The inner ring 40 may comprise polysilicon. A contact pad 50 may be formed within the inner ring 40. The contact pad 50 may be operatively connected to the inner ring 40. The contact pad 50 may comprise a metal. An insulating region 60 may be formed between the outer ring 30 and the inner ring 40. The insulating region 60 may comprise polysilicon, silicon dioxide or a mixture of polysilicon and silicon dioxide or any other insulating material or a mixture of all these. As shown in FIG. 2, a plurality of removable fingers 70 may be formed between the outer ring 30 and the inner ring 40. The plurality of removable fingers 70 may operatively connect the outer ring 30 to the inner ring 40. The plurality of removable fingers 70 may comprise polysilicon. As shown in FIG. 2, a plurality of removable fingers 70 may be a very low resistance for the connection between the active region 20 and the contact pad 50 which is determinative of the resistance of the semiconductor device 10, e.g., the gate resistance of the transistor.

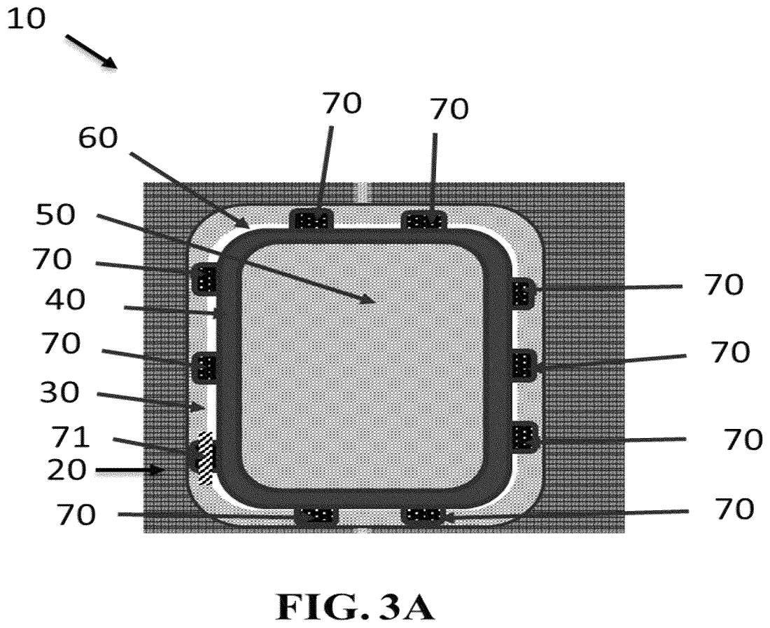

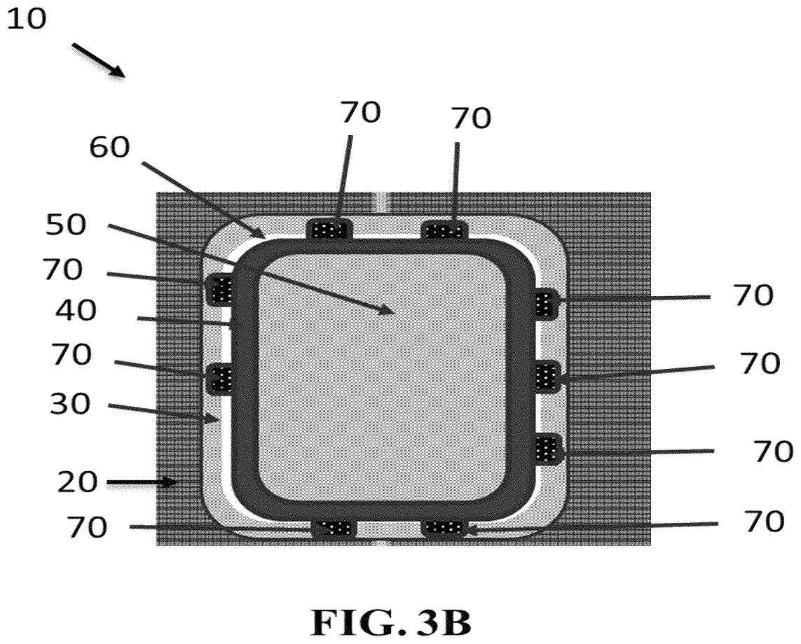

FIGS. 3A-3B show an illustration of a semiconductor device 10 according to one or more examples wherein one of the removable fingers 71 may be removed from the plurality of removable fingers 70 of the semiconductor device 10. The semiconductor device 10 may represent a transistor, and may be called a MOSFET, without limitation. Semiconductor device 10 may include an active region 20. The active region 20 may comprise an n-type dopant or the active region 20 may comprise a p-type dopant. An outer ring 30 may be formed within the active region 20. The outer ring 30 may be operatively connected to the active region 20. The outer ring 30 may comprise polysilicon. An inner ring 40 may be formed within the outer ring 30. The inner ring 40 may comprise polysilicon. A contact pad 50 may be formed within the inner ring 40. The contact pad 50 may be operatively connected to the inner ring 40. The contact pad 50 may comprise a metal. An insulating region 60 may be formed between the outer ring 30 and the inner ring 40. The insulating region 60 may comprise polysilicon, silicon dioxide or a mixture of polysilicon and silicon dioxide or any other insulating material or a mixture of all these. As shown in FIGS. 3A-3B, a plurality of removable fingers 70, 71 may be formed between the outer ring 30 and the inner ring 40. The plurality of removable fingers 70, 71 may operatively connect the outer ring 30 to the inner ring 40. As shown in FIG. 3A, a removable finger 71 of the plurality of removable fingers 70 may be marked for removal. As shown in FIG. 3B, the marked removable finger 71 of FIG. 3A of the plurality of removable fingers 70 has been removed. As shown in FIG. 3B vs. 3A, the removal of removable finger 71 from the plurality of the removable fingers 70 increases the resistance for the connection between the active region 20 and the contact pad 50 which is determinative of the resistance of the semiconductor device 10, e.g., the gate resistance of the transistor.

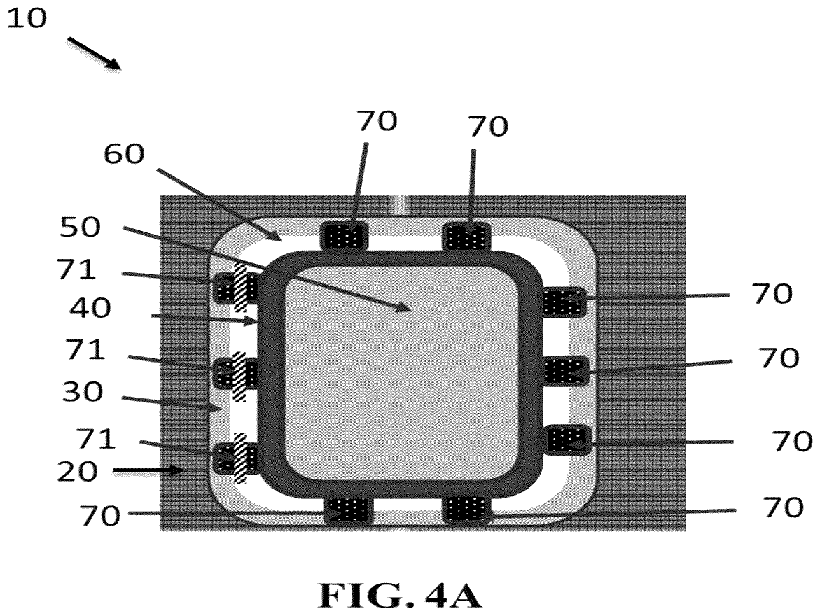

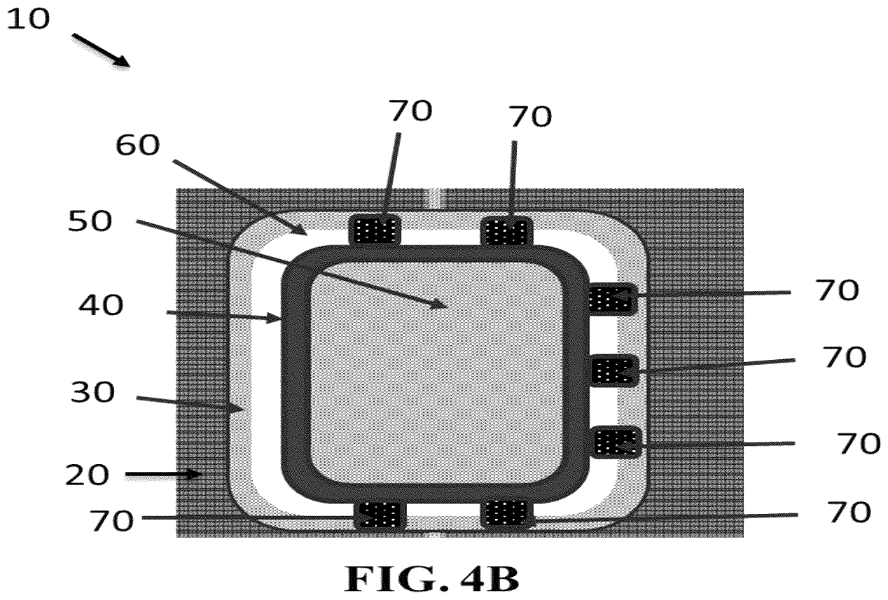

FIGS. 4A-4B show an illustration of a semiconductor device 10 according to one or more examples wherein three of the plurality of removable fingers 71 may be removed from the plurality of removable fingers 70 of the semiconductor device 10. The semiconductor device 10 may represent a transistor, and may be called a MOSFET, without limitation. Semiconductor device 10 may include an active region 20. The active region 20 may comprise an n-type dopant or the active region 20 may comprise a p-type dopant. An outer ring 30 may be formed within the active region 20. The outer ring 30 may be operatively connected to the active region 20. The outer ring 30 may comprise polysilicon. An inner ring 40 may be formed within the outer ring 30. The inner ring 40 may comprise polysilicon. A contact pad 50 may be formed within the inner ring 40. The contact pad 50 may be operatively connected to the inner ring 40. The contact pad 50 may comprise a metal. An insulating region 60 may be formed between the outer ring 30 and the inner ring 40. The insulating region 60 may comprise polysilicon, silicon dioxide or a mixture of polysilicon and silicon dioxide or any other insulating material or a mixture of all these. As shown in FIGS. 3A-3B, a plurality of removable fingers 70, 71 may be formed between the outer ring 30 and the inner ring 40. The plurality of removable fingers 70, 71 may operatively connect the outer ring 30 to the inner ring 40. As shown in FIG. 3A, three removable fingers 71 of the plurality of removable fingers 70 may be marked for removal. As shown in FIG. 3B, the three marked removable fingers 71 of FIG. 3A of the plurality of removable fingers 70 have been removed. As shown in FIG. 3B vs. 3A, the removal of the three removable fingers 71 from the plurality of the removable fingers 70 increases the resistance for the connection between the active region 20 and the contact pad 50 which is determinative of the resistance of the semiconductor device 10, e.g., the gate resistance of the transistor.

The method of manufacturing a semiconductor device 10 according to one or more examples. The semiconductor device 10 may represent a transistor, and may be called a MOSFET, without limitation. The method may include forming an active region 20. The active region 20 may comprise an n-type dopant or the active region 20 may comprise a p-type dopant. The method may include forming an outer ring 30 within the active region 20. The outer ring 30 may be operatively connected to the active region 20. The outer ring 30 may comprise polysilicon. The method may include forming an inner ring 40 within the outer ring 30. The inner ring 40 may comprise polysilicon. The method may include forming a contact pad 50 within the inner ring 40. The contact pad 50 may be operatively connected to the inner ring 40. The contact pad 50 may comprise a metal. The method may include forming an insulating region 60 between the outer ring 30 and the inner ring 40. The insulating region 60 may comprise polysilicon, silicon dioxide or a mixture of polysilicon and silicon dioxide or any other insulating material or a mixture of all these. The method may include forming a single removable finger 70 between the outer ring 30 and the inner ring 40 as shown in FIG. 1 or the method may include forming a plurality of removable fingers 70 between the outer ring 30 and the inner ring 40 as shown in FIG. 2. The removable finger 70 of FIG. 1 or plurality of removable fingers 70 of FIG. 2 may operatively connect the outer ring 30 to the inner ring 40. The removable finger 70 of FIG. 1 or plurality of removable fingers 70 of FIG. 2 may comprise polysilicon. With only a single removable finger as shown in FIG. 1, there is a very high resistance between the active region 20 and the contact pad 50 which is determinative of the resistance of the semiconductor device 10, e.g., the gate resistance of the transistor. Alternatively, a plurality of removable fingers as shown in FIG. 2 may be a very low resistance for the connection between the active region 20 and the contact pad 50 which is determinative of the resistance of the semiconductor device 10, e.g., the gate resistance of the transistor. The semiconductor device 10 may have a single removable finger 71 removed to adjust the resistance of the semiconductor device 10 as shown in FIGS. 3A-3B. Alternatively, the semiconductor device 10 may have multiple removable fingers 71, e.g. three removable fingers 71, removed to adjust the resistance of the semiconductor device 10 as shown in FIGS. 4A-4B.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A semiconductor device comprising:
an active region;
an outer ring formed within the active region, the outer ring is operatively connected to the active region;
an inner ring formed within the outer ring;
a contact pad formed within the inner ring, the contact pad is operatively connected to the inner ring;
an insulating region formed between the outer ring and the inner ring; and
a removable finger formed between the outer ring and the inner ring, the removable finger operatively connects the outer ring to the inner ring.

2. The device of claim 1, wherein the active region comprises an n-type dopant.

3. The device of claim 1, wherein the active region comprises a p-type dopant.

4. The device of claim 1, wherein the contact pad comprises a metal.

5. The device of claim 1, wherein the outer ring comprises polysilicon.

6. The device of claim 5, wherein the inner ring comprises polysilicon.

7. The device of claim 6, wherein the removable finger comprises polysilicon.

8. A semiconductor device comprising:
an active region;
an outer ring formed within the active region, the outer ring is operatively connected to the active region;
an inner ring formed within the inner ring;
a contact pad formed within the inner ring, the contact pad is operatively connected to the inner ring;
an insulating region formed between the outer ring and the inner ring; and
a plurality of removable fingers formed between the outer ring and the inner ring, the plurality of removable fingers operatively connects the outer ring to the inner ring.

9. The device of claim 8, wherein the active region comprises an n-type dopant.

10. The device of claim 8, wherein the active region comprises a p-type dopant.

11. The device of claim 8, wherein the contact pad comprises a metal.

12. The device of claim 8, wherein the outer ring comprises polysilicon.

13. The device of claim 12, wherein the inner ring comprises polysilicon.

14. The device of claim 13, wherein the plurality of removable fingers comprises polysilicon.

15. A method of manufacturing a semiconductor device, the method comprising:
forming an active region;
forming an outer ring within the active region, the outer ring is operatively connected to the active region;
forming an inner ring within the outer ring;
forming a contact pad within the inner ring, the contact pad is operatively connected to the inner ring;
forming an insulating region between the outer ring and the inner ring; and
forming a removable finger between the outer ring and the inner ring, the removable finger operatively connecting the outer ring to the inner ring.

16. The method of claim 15, wherein the active region comprises an n-type dopant.

17. The method of claim 15, wherein the active region comprises a p-type dopant.

18. The method of claim 15, wherein the contact pad comprises a metal.

19. The method of claim 15, wherein the outer ring comprises polysilicon.

20. The method of claim 19, wherein the inner ring comprises polysilicon.

21. The method of claim 20, wherein the removable finger comprises polysilicon.

22. The method of claim 15, wherein the method comprises forming a plurality of removable fingers.
